(19) United States
(12) Patent Application Publication
(10) Pub. No.: US 2019/0116657 A1
(43) Pub. Date: Apr. 18, 2019

(54) THERMALLY ENHANCED PRINTED CIRCUIT BOARD ARCHITECTURE FOR HIGH POWER ELECTRONICS

(71) Applicant: Stryke Industries, LLC, Fort Wayne, IN (US)

(72) Inventors: Ian Fuller, Bellbrook, OH (US); Van Flamion, Warsaw, IN (US)

(73) Assignee: Stryke Industries, LLC, Fort Wayne, IN (US)

(21) Appl. No.: 16/162,749

(22) Filed: Oct. 17, 2018

Related U.S. Application Data
(60) Provisional application No. 62/573,927, filed on Oct. 18, 2017.

(51) Int. Cl. H05K 1/02; H05K 1/03; H05K 1/05; H05K 1/11; B32B 15/20; B32B 15/08

(52) U.S. Cl. CPC H05K 1/0207; H05K 1/0346; H05K 1/056; B32B 15/08; H05K 1/115; B32B 15/20; H05K 1/0306

(57) ABSTRACT

A thermally enhanced printed circuit board architecture includes one or more electrically insulating composite layers, one or more electrically conductive layers, and one or more thermally conductive layers assembled into a stack.

### FIELD OF THE DISCLOSURE

This disclosure relates generally to a printed circuit board/printed wiring board (“PCB/PWB”) architecture wherein one or more highly thermally conductive materials are incorporated to assist in thermal dissipation from integrated chips and other heat producing components. More specifically, the disclosure relates to one or more thermally conductive layers placed in working contact between adjacent layers of the PCB structure.

### BACKGROUND OF THE PRESENT DISCLOSURE

In current applications, conductive layers, most often comprised of copper or aluminum materials, are utilized to conduct electrical signals between different interconnected sections of a printed circuit board (“PCB”). This conductive layer is most typically laminated to an insulating substrate such as a glass fiber/epoxy composite material (commercially referred to as “FR-4”) with this assembly being repeated one or more times to generate the necessary number of board layers. A critical, but often overlooked, function of this conductive layer is the thermal dissipation from on-board components such as integrated chips (“ICs”). Today's high-power, high-speed electronics generate significant heat that can degrade the performance and lifespan of the ICs and other components if not properly dissipated or managed.

Most state-of-the-art electronic thermal management techniques revolve around adding additional conduction or convection paths exterior to the PCB itself. Often, the thermal considerations of the PCB are viewed and considered as a single component with a maximum operating temperature and a known thermal dissipation rate. However, the different components on the surface of the PCB contribute vastly different amounts to the thermal profile of the entire system. High power chips such as amplifiers, processors, and other high-frequency circuits can generate extremely high and extremely localized temperature profiles that, if not dealt with, will significantly limit their operating clock speeds, operating environments, or both.

### SUMMARY OF THE DISCLOSURE

To this end, the present disclosure pertains to incorporating, internal to the PCB architecture, a highly thermally conductive layer whose primary function is the dissipation of heat from such high-powered electronics to lower temperature areas of the board. This dissipation effect would work to significantly reduce the maximum localized temperature across the board and may assist in the eventual removal of heat to outside thermal management systems. This highly conductive layer may be placed in working contact between electrically insulating composite layers and would work in tandem with traditional electrically conductive layers such as copper or aluminum. As PCB components are energized and begin to increase in temperature due to electrical resistances, the thermally conductive layers, thermally connected to one or more areas of the PCB, would work to efficiently and rapidly dissipate the heat, thereby reducing the components' overall temperature. The present disclosure enhances the applicability and performance specifications of high-powered electronics and potentially provides a framework for electronic thermal management systems into the future.

In one embodiment of the present disclosure, a printed circuit board structure comprises one or more electrically insulating composite layers, one or more electrically conductive layers, and one or more thermally conductive layers. The one or more thermally conductive layers is comprised of a highly oriented material,

In another embodiment of the present disclosure, a printed circuit board structure comprises a copper layer, an electrically insulating layer positioned in spaced relation to the electrically conductive layer, and a carbon layer positioned adjacent the electrically insulating layer and comprised of highly oriented sub-units (graphene platelets, crystallites, or carbon fibers, for example).

In a further embodiment of the present disclosure, a printed circuit board structure comprises an electrically conductive portion, an electrically insulating portion, and a thermally conductive portion comprised of a highly oriented material having at least 95 weight % carbon and sub-units positioned generally parallel each other. The thermally conductive portion is positioned adjacent the electrically conductive portion and the electrically insulating portion.

### BRIEF DESCRIPTION OF THE DRAWINGS

The above mentioned and other features of this invention, and the manner of attaining them, will become more apparent and the invention itself will be better understood by reference to the following description of embodiments of the invention taken in conjunction with the accompanying drawings, where:

FIG. 1 is a cross-sectional view of a multi-layer printed circuit board architecture of the present disclosure, including electrically conductive layers, electrically insulating composite materials, and one or more thermally conductive layers placed between the composite layers;

FIG. 2A is a cross-sectional view of a multi-layer printed circuit board architecture of the present disclosure, including electrically conductive layers, electrically insulating composite materials, and one or more thermally conductive layers placed in working contact with the electrically conductive layers;

FIG. 2B is a cross-sectional view of a multi-layer printed circuit board architecture of the present disclosure, including at least one electrically conductive layer coated with a highly-oriented thermally conductive layer and positioned adjacent an electrically insulating composite layer;

FIG. 2C is a cross-sectional view of the thermally conductive layer of the present application with a coating layer applied thereto;

FIG. 2D is a cross-sectional view of the thermally conductive layer coated with at least one electrically conductive layer;

FIG. 3 is a schematic view of the printed circuit board architecture of the present disclosure, illustrating experimental operating temperatures of a surface mount power resistor and thermal gradients across the PCB when highly oriented graphite is utilized as the thermally conductive layer; and

FIG. 4 is a schematic view of the traditional printed circuit board architecture, illustrating experimental operating temperatures of a surface mount power resistor and thermal gradients across the PCB when traditional one-ounce copper is utilized as the thermally conductive layer.

Corresponding reference characters indicate corresponding parts throughout the several views. Although the drawings represent embodiments of the present invention, the drawings are not necessarily to scale and certain features may be exaggerated in order to better illustrate and explain the present invention.

### DETAILED DESCRIPTION OF THE DRAWINGS

The embodiments disclosed below are not intended to be exhaustive or to limit the invention to the precise forms disclosed in the following detailed description. Rather, the embodiments are chosen and described so that others skilled in the art may utilize their teachings.

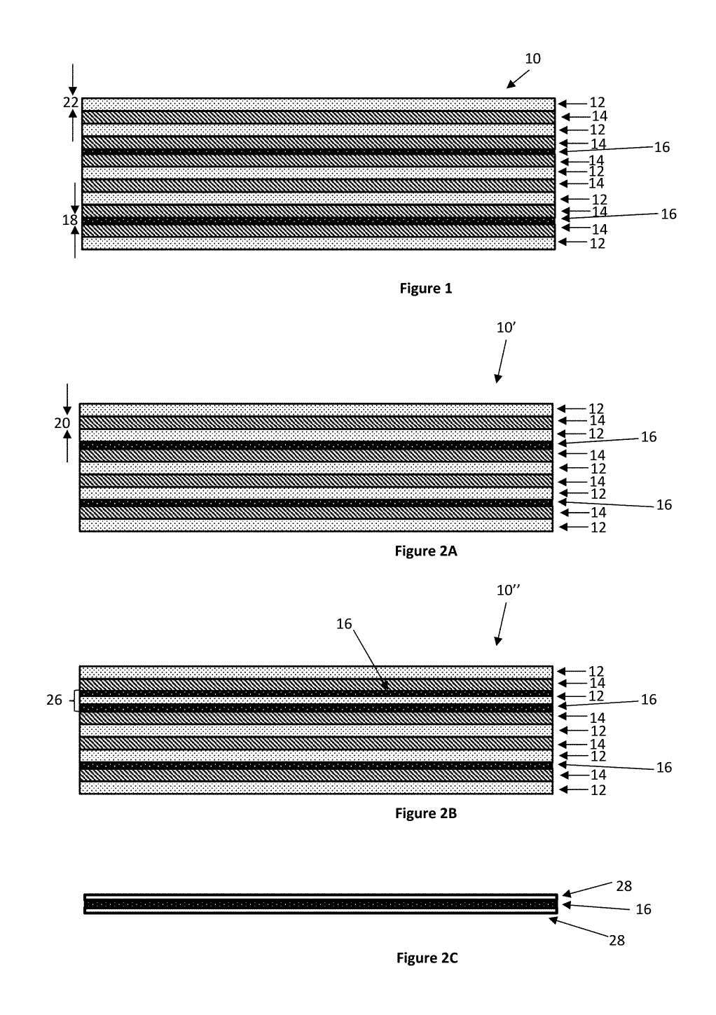

With respect to FIGS. 1 and 2A-C, the present disclosure relates to a printed circuit board (“PCB”) structure or architecture 10 where the dissipation and transport of thermal energy is performed primarily by a highly thermally conductive layer internal to the PCB structure 10. For example, and referring to FIG. 1, the printed circuit board structure 10 of the present disclosure may include electrically conductive layers 12 (e.g., copper or aluminum), electrically insulating composite layers or materials 14, such as those made of glass fiber/epoxy composite materials (e.g., FR-4 or similar composite layers), PTFE, PI, or PPO, and one or more thermally conductive layers 16 configured in a generally stacked arrangement. In the embodiment of FIG. 1, the majority of the electrical energy is transported through the electrically conductive layers 12, while the majority of the thermal energy is transported through the thermally conductive layers 16. Illustratively, the thermally conductive layer 16 of FIG. 1 is incorporated between two electrically insulating composite layers 14. However, as shown in FIG. 2A, the orientation of layers of the PCB structure 10′ is ordered as the electrically conductive layer (e.g., copper) 12, the electrically insulating layer 14, the electrically conductive layer 12, the thermally conductive layer 16, the electrically insulating layer 14, etc. Alternatively, as shown in FIG. 2B, the PCB structure 10″ is ordered as the electrically conductive layer 12, the electrically insulating layer 14, and another electrically conductive layer 12 sandwiched or generally encompassed between two thermally conductive layers 16. Additionally, as shown in FIG. 2D, the thermally conductive layer 16 may be sandwiched between or coated with two electrically conductive layers 12. As such, the present disclosure includes various combinations of layers 12, 14, 16.

Alternatively, another illustrative embodiment of PCB is shown as PCB 10′ in FIGS. 2A-B and provides an example wherein the thermally conductive layer 16 is incorporated between an electrically insulating layer 14 and an electrically conductive layer 12 (e.g., copper or aluminum). In this way, the thermally conductive layer 16 can be positioned adjacent/in working contact with electrically conductive layer 12 and/or electrically insulating composite layer 14, as shown in FIGS. 1 and 2A-B. The ability to select the layer structure of the PCB 10, 10′, where the thermally conductive layer 16 is placed with respect to the other layers, allows for greater flexibility in manufacturing processes. As an example, the thermally conductive layer 16 may comprise graphene and diamond coatings which can be readily grown on copper substrates, such as the electrically conductive layer 12. Additionally, the thermally conductive layer 16 may comprise a coating on the electrically insulating layer 14. It may be appreciated that coating the electrically insulating layer 14 with the thermally conductive layer 16 may present differences in the manufacturing process as compared to growing the coating on the electrically conductive layer 12 and, in particular, may be more challenging to manufacture but still achievable, as shown in FIGS. 1 and 2A-B. As such, the placement of the thermally conductive layer 16 can be optimized based on the selection of the thermally conductive material and the desired application process.

The thermally conductive layer 16 may have a thickness 18 of between 10 nm and 1 mm. Additionally, the electrically insulating layer 14 may have a thickness 20 of approximately 0.5-5.0 mm and, more particularly, approximately 0.8-4.0 mm. Also, the thickness 22 of the electrically conductive layer 12 may be approximately 10-100 μm.

Referring still to FIGS. 1 and 2A-B, the electrically insulating composite layer 14 may be comprised of at least one insulating polymer, elastomer, or ceramic. In one embodiment, the electrically insulating layer 14 may be comprised of any combination of epoxy, vinyl ester, polyester, cyanate ester, polyimide, and bismaleimide triazine with or without reinforcing materials such as, but not limited to, E-glass fiber, aramid fiber, quartz fiber, basalt fiber, and combinations thereof, or any functional equivalent thereof. This insulating composite layer may be between 0.5 and 5.0 mm in thickness.

Referring still to FIGS. 1 and 2A-B, with respect to the thermally conductive layers 16 of the PCB structure 10, 10′, the thermally conductive layer 16 is comprised of a highly thermally conductive material including, but not limited to graphite, graphene, carbon nanotubes, carbon fiber, highly oriented pyrolytic graphite (HOPG), highly oriented graphite, annealed pyrolytic graphite (APG), diamond, and combinations thereof. In one embodiment, the thermally conductive layer 16 is comprised of at least approximately 95 weight % carbon. The material comprising the thermally conductive layer 16 is highly oriented in that any material sub-unit or other similar structure of the material are aligned in the same direction and are generally parallel to each other. This orientation may provide significant functional benefits by imparting anisotropic thermal properties wherein the thermal conductivity in one or two geometric axes (in the X-Y plane of the layer, for example) is substantially higher than in a perpendicular geometric axis (in the through-layer Z plane, for example). As disclosed further herein, the thermally conductive layer 16 of the present disclosure includes a highly oriented material, such as HOPG, highly oriented graphite, annealed pyrolytic graphite, and other materials, and the highly oriented nature of such materials increase the thermal conductivity of the thermally conductive layer 16, thereby increasing the thermal dissipation ability of the PCB structure 10, 10′.

As disclosed herein, the thermally conductive layer 16 of the PCB structure 10, 10′ is comprised of a carbon-based material and may be configured as a coating but the illustrative thermally conductive layer 16 also may be comprised as a particulate material, a sheet or planar member such as a porous mat, foil, or perforated foil, a fiber or series of fibers, or any combination thereof. Additionally, as disclosed herein, the thermally conductive layer 16 also may comprise graphene and diamond coatings which can be readily grown on copper substrates, such as the electrically conductive layer 12. Additionally, the thermally conductive layer 16 may comprise a coating on the electrically insulating layer 14.

More particularly, in one embodiment, the thermally conductive layer 16 may undergo chemical or physical treatments, including but not limited to, plasma, corona, or chemical etching, to promote surface adhesion between the thermally conductive layer 16 and adjoining layers (e.g., the electrically conductive layer 12 and/or the electrically insulating composite layer 14). In one embodiment, the thermally conductive layer 16 is configured as a coating onto either the electrically conductive layer 12 or the insulating composite layer 14. In this way, the electrically conductive layer 12 may be coated with the material comprising the thermally conductive layer 16 such that a single sheet 26 is configured to handle both the electrical and thermal loads in this single layer 26, as shown in FIG. 2B. In such an embodiment, the thickness of the single sheet 26 is approximately 10 μm-2.1 mm. In addition thereto, or as an alternative embodiment, the thermally conductive layer 16 may be coated with a coating 28, as shown in FIG. 2C, before joining with layers 12 and/or 14. In such an embodiment, the coating 28 may be comprised of Ni, Pd, Cu, Al, Ti, Cr, Au, Ag, Pt, or any combination thereof and have a thickness of at least approximately 0.000005 inch. If the thermally conductive layer 16 is first coated with the materials listed herein or itself is applied as a coating to layers 12 and/or 14, the coating may be applied through plasma spray, wire arc spray, cold spray, chemical vapor deposition, physical vapor deposition, electrophoresis, evaporation, electroplating, gravure, slot die and other roll-to-roll coating process, spin coating, dip coating, or similar processes. Additionally, the thermally conductive layer 16 may undergo a mechanical abrading process to promote adhesion with the adjacent electrically conductive layer 12 and/or the electrically insulating composite layer 14.

Additionally, as shown in FIG. 2D, the thermally conductive layer 16 may be coated with at least one electrically conductive layer 12, such that copper, aluminum, or any other material comprising the electrically conductive layer 12 is coated onto the thermally conductive layer 16 to form a single sheet of the PCB 10, 10′. In this way, and as disclosed herein, the thickness thereof may be reduced to compared to distinct layers 12, 16, thereby contributing to a reduced overall thickness of the PCB 10, 10′. In such an embodiment, the thickness of this single sheet is approximately 10 μm-2.1 mm.

The thermally conductive layer 16 may be physically, chemically, and/or thermally modified or altered to modify the electrical properties and electrically insulate the layer from various electrical and/or thermal interconnects. For example, the thermally conductive layer 16 may be physically altered through drilling, cutting, water jetting, laser cutting, and/or similar processes; may be chemically modified through chemical oxidation; and/or may be thermally modified through thermal oxidation, laser-induced oxidation, and/or similar processes.

The heat producing components, such as an energized surface mount power resistor 24 (e.g., 17 W dissipated), are generally located on one or both outer layers of the PCB structure 10, 10′. These components are placed on electrically conductive pads for connection to other components in a prescribed manner. This interconnected electrical network is typically achieved using in-plane and/or through-plane electrically conductive traces. For the thermal consideration, the heat produced by these components may be conducted to both the electrically conductive layer 12 and the thermally conductive layer 16 through two primary methods: (1) through the thickness 20 of the insulating composite layers 14; or (2) by conduction through electrically and thermally conductive traces, commonly referred to as vias (“vertical interconnect access”). Once conducted from the outer layer(s) of the PCB structure 10, 10′ to the inner layers thereof through one of these two methods, the addition of the highly thermally conductive layer 16 more rapidly dissipates the thermal energy, thereby allowing cooler operation of the components of the PCB structure 10, 10′.

More particularly, the highly-oriented configuration of the material comprising the thermally conductive layer 16 allows for this increased dissipation of thermal energy. The orientation of the thermally conductive layer 16 may be customized and tailored to the specific application, thermal requirements, etc. of the PCB structure 10, 10′ and may be defined during the manufacturing process of the PCB structure 10, 10′. By using a highly oriented material for the thermally conductive layer 16, the thermally conductive layer 16 has a different thermal conductivity value in-plane compared to the thermal conductivity value through-plane and, specifically, has a higher thermal conductivity value in-plane than that of the through-plane value. This anisotropic configuration, wherein the thermally conductive layer 16 has higher in-plane thermal conductivity than through-plane, would help to dissipate localized heating (i.e. from a high-power IC), across a larger surface area of the PCB thereby reducing the maximum temperature of the heat source. Because the thermally conductive layer 16 may be comprised of a highly oriented material, it is this orientation of the sub-components or sub-units (e.g., graphene platelets, crystallites, or carbon fibers, for example) within the thermally conductive layer 16 that allows for heat to transfer in the preferred orientation, resulting in increased dissipation of heat away from the heat producing component(s) of the PCB structure 10, 10′. Comparatively, a traditional graphite sheet or plate may be isotropic where the sub-units therein are randomly oriented.

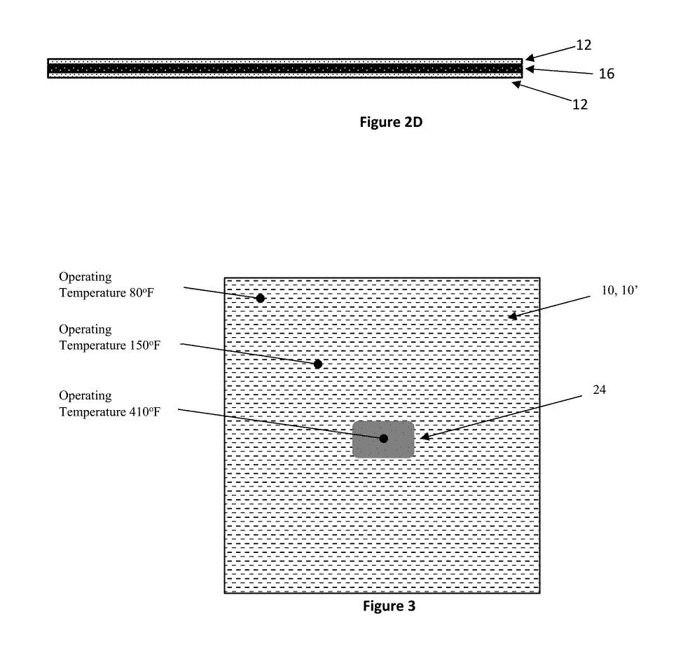

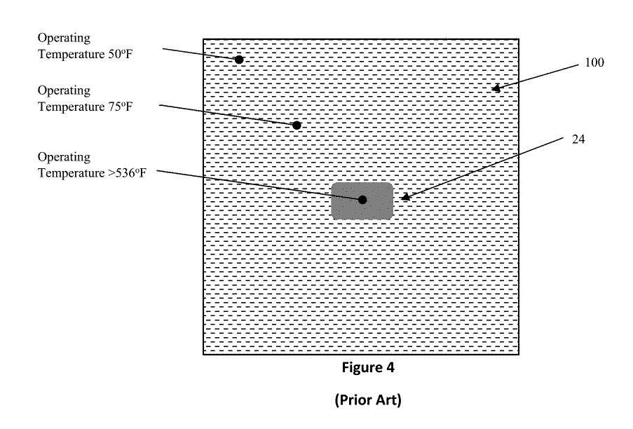

In operation, and referring to FIG. 3, compared to traditional and commonly employed PCB materials, the PCB structure 10, 10′ of the present disclosure has the ability to reduce localized integrated chip temperatures, thereby reducing localized “hot spots” and potentially increasing the board lifetime, maximum operating speeds, and/or performance. To illustrate this concept, example temperatures are given in FIG. 3 and FIG. 4 as determined by experimental results. For example, FIG. 3 illustrates that the thermally conductive layer 16 of the PCB structure 10, 10′ of the present disclosure is comprised of a highly-oriented material, e.g., annealed pyrolytic graphite, and has a thermal effect on chip and board temperatures as compared to FIG. 4, which utilized a traditional, one-ounce copper layer as the thermally conductive layer. More particularly, the prior art PCB architecture of FIG. 4 does not include the thermally conductive layer of the present disclosure and, therefore, the heat producing component, for example the surface mounted power resistor 24, experiences a significantly higher operating temperature (>536° F. in FIG. 4 without the thermally conductive layer 16 compared to 410° F. with the thermally conductive layer 16). More particularly, as shown in FIGS. 3 and 4, the PCB structure 10, 10′ of FIG. 3 with the highly-oriented thermally conductive layer 16 allows for increased heat dissipation away from the resistor 24 and more even distribution of the heat experienced by the PCB structure 10, 10′ which decreased any localized “hot spots” at the location of the resistor 24. This heat dissipation ability of layer 16 is attributed to the anisotropic property of the material comprising layer 16 because the material is highly oriented with greater in-plane thermal conductivity compared through-plane thermal conductivity. Conversely, the embodiment of FIG. 4 without the thermally conductive layer 16 maintains a significantly higher operating temperature at the location of the resistor 24, thereby resulting in a localized “hot spot.”

The electrical and thermal conduction contributions, under ideal conditions, are dictated by Ohm's law by the respective electrical and thermal resistances of the different layers. For the purposes of theoretical demonstration, the electrical resistivity of copper is typically near 1.7E-8 Ω-m while highly oriented graphite is typically near 4E-6 Ω-m. In regard to thermal properties, the thermal resistivity of copper is 2.5E-3 m-K/W while highly oriented graphite is typically near 5.9E-4 m-K/W. The proportion of these resistances provides the theoretical contribution of each layer. Under these ideal conditions, the copper layer will conduct 99.6% of the electrical current while the highly oriented graphite would conduct 76.4% of the thermal current. In this way, the configuration of the PCB structure 10, 10′ of the present application allows for increased thermal dissipation across the surface area of the board, thereby contributing to a reduction in the maximum chip operating temperature. In addition, by efficiently spreading the heat across the PCB structure 10, 10′, conduction pathways off the board (e.g., wedge locks or mounting bolts), which are typically located near the edge of the PCB, and therefore a large distance from the heat producing components, are more efficiently utilized to conduct heat off the board to some external heat sink or large thermal mass. It may be appreciated that wedge locks or mounting bolts are positioned outside of the PCB structure 10, 10′ and may be used to support the PCB structure 10, 10′ within a frame or other arrangement and also provide for heat dissipation away from the heat producing components.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A printed circuit board structure, comprising:
one or more electrically insulating composite layers;
one or more electrically conductive layers;
and one or more thermally conductive layers, wherein the one or more thermally conductive layers is comprised of a highly oriented material.

2. The printed circuit board structure of claim 1, wherein the highly oriented material comprises at least approximately 95 weight % carbon.

3. The printed circuit board structure of claim 2, wherein the highly oriented material is comprised of at least one of graphite, graphene, carbon nanotubes, carbon fiber, and diamond.

4. The printed circuit board structure of claim 1, wherein the one or more thermally conductive layer is configured as a coating on at least one of the one or more electrically insulating composite layers.

5. The printed circuit board structure of claim 4, wherein the one or more thermally conductive layer is configured as a coating on at least one of the one or more electrically conductive layers.

6. The printed circuit board structure of claim 1, wherein one of the one or more thermally conductive layers is positioned adjacent one of the one or more electrically conductive layers.

7. The printed circuit board structure of claim 7, wherein the one electrically conductive layer is comprised of copper and the one thermally conductive layer is comprised of a carbon material.

8. The printed circuit board structure of claim 7, wherein the carbon material is coated onto the copper layer to define a single sheet of the printed circuit board structure.

9. The printed circuit board structure of claim 7, wherein the carbon material is positioned adjacent and in contact with an upper layer of copper and a lower layer of copper.

10. The printed circuit board structure of claim 7, wherein copper is positioned adjacent and in contact with an upper layer of the carbon material and a lower layer of the carbon material.

11. A printed circuit board structure, comprising:
a copper layer;
an electrically insulating layer positioned in spaced relation to the electrically conductive layer; and
a carbon layer positioned adjacent the electrically insulating layer and comprised of highly oriented crystallites.

12. The printed circuit board structure of claim 11, wherein the carbon layer also is positioned adjacent the copper layer.

13. The printed circuit board structure of claim 12, wherein the carbon layer is configured as a coating on the copper layer.

14. The printed circuit board structure of claim 11, wherein the carbon layer is configured to dissipate heat in an in-plane manner.

15. A printed circuit board structure, comprising:
an electrically conductive portion;
an electrically insulating portion; and
a thermally conductive portion comprised of a highly oriented material having at least 95 weight % carbon and sub-units positioned generally parallel each other, and the thermally conductive portion being positioned adjacent the electrically conductive portion and the electrically insulating portion.

16. The printed circuit board structure of claim 15, wherein the electrically conductive portion is comprised of at least one of copper and aluminum and the electrically insulating portion is comprised of at least one polymer, elastomer, and ceramic.

17. The printed circuit board structure of claim 16, wherein the electrically insulating portion is comprised of at least one of epoxy, vinyl ester, polyester, cyanate ester, polyimide, and bismaleimide triazine.

18. The printed circuit board structure of claim 17, wherein the electrically insulating portion is further comprised of reinforcing materials comprised of at least one of E-glass fiber, aramid fiber, quartz fiber, and basalt fiber.

19. The printed circuit board structure of claim 17, wherein the electrically insulating portion has a thickness of approximately 0.5-5.0 mm, the electrically conductive portion has a thickness of approximately 10-100 μm, and the thermally conductive portion has a thickness of approximately 10 nm-1 mm.

20. The printed circuit board structure of claim 15, wherein the thermally conductive portion includes a coating comprised of at least one of Ni, Pd, Cu, Al, Ti, Cr, Au, Ag, and Pt.

21. The printed circuit board structure of claim 15, wherein the thermally conductive portion is configured as a coating on the electrically conductive portion to define a single sheet of the printed circuit board structure.

22. The printed circuit board structure of claim 21, wherein a thickness of the single sheet is approximately 10 μm-2.1 mm.

23. The printed circuit board structure of claim 15, wherein the thermally conductive portion is at least one of physically altered through drilling, cutting, water jetting, or laser cutting, chemically modified through chemical oxidation, and thermally modified through thermal oxidation or laser-induced oxidation.
